(19) United States
(12) Patent Application Publication
(10) Pub. No.: US 2013/0256780 A1
(43) Pub. Date: Oct. 3, 2013

(54) SEMICONDUCTOR DEVICE AND MANUFACTURING METHOD THEREOF

(71) Applicant: KABUSHIKI KAISHA TOSHIBA, Tokyo (JP)

(72) Inventors: Tetsuya KAI, Kanagawa-ken (JP); Masayuki TANAKA, Kanagawa-ken (JP)

(73) Assignee: Kabushiki Kaisha Toshiba, Tokyo (JP)

(21) Appl. No.: 13/792,538

(22) Filed: Mar. 11, 2013

(30) Foreign Application Priority Data
Mar. 30, 2012 (JP) 2012-082863

(51) Int. Cl. H01L 29/792

(52) U.S. Cl. CPC H01L 29/792
USPC 257/324

(57) ABSTRACT

A semiconductor device comprising: a semiconductor substrate; a tunnel insulating film provided on the semiconductor substrate; a charge accumulation film having a rough interface in the charge accumulation film provided on the tunnel insulating film; a block insulating film provided on the charge accumulation film; and a gate electrode provided on the block insulating film.

### CROSS-REFERENCE TO RELATED APPLICATIONS

This application is based upon and claims the benefit of priority from the prior Japanese Patent Application No. 2012-82863, filed 30 Mar. 2012, the entire contents of which are incorporated herein by reference.

### FIELD

Embodiments described herein relate to semiconductor device and manufacturing method thereof.

### BACKGROUND

For example, in a charge-storage-type non-volatile semiconductor memory device such as a NAND flash memory, writing or erasing operation is controlled by potentials of control gates. However, when the memory devices are going to minimize a charge accumulation film, the memory devices are thinner so that electron-trap-sites reduce. Therefore, the performance of the memory devices decreases.

### DESCRIPTION OF THE DRAWINGS

FIG. 1A is a cross-sectional view showing a cross-sectional structure in a direction perpendicular to a word line of a semiconductor device of a first embodiment;

FIG. 1B is a cross-sectional view showing a cross-sectional structure in a direction perpendicular to a bit line of the semiconductor device of the first embodiment;

FIG. 2 is an enlarged cross-sectional view showing a structure of a charge accumulation film of the semiconductor device of the first embodiment;

FIG. 3 is a cross-sectional view showing cross sections of the semiconductor device of the first embodiment in respective manufacturing processes thereof; and

FIG. 4 is an enlarged cross-sectional view showing a structure of a charge accumulation film in of a semiconductor device of a second embodiment.

### DETAILED DESCRIPTION

Embodiments of the present invention are described below with reference to the drawings. In the description, the same portions are denoted by the same reference numerals throughout the drawings. Moreover, dimensional ratios in the drawings are not limited only to the illustrated ratios. Note that the embodiments do not limit the present invention.

### First Embodiment

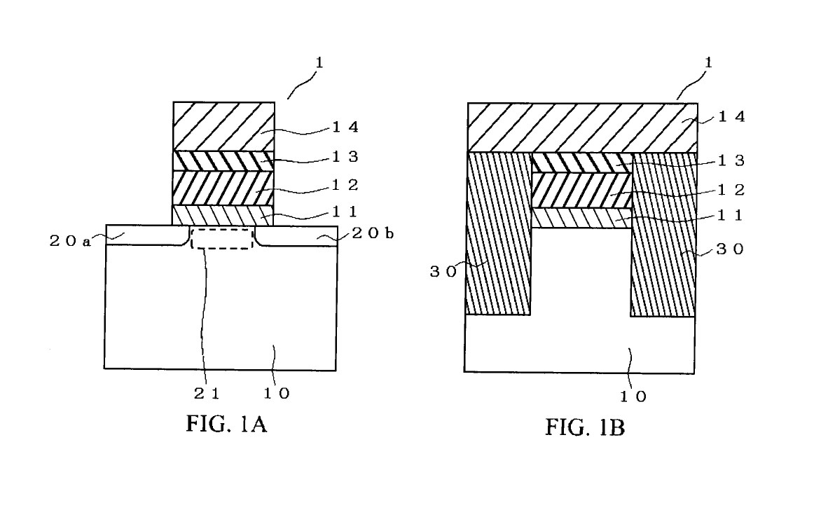

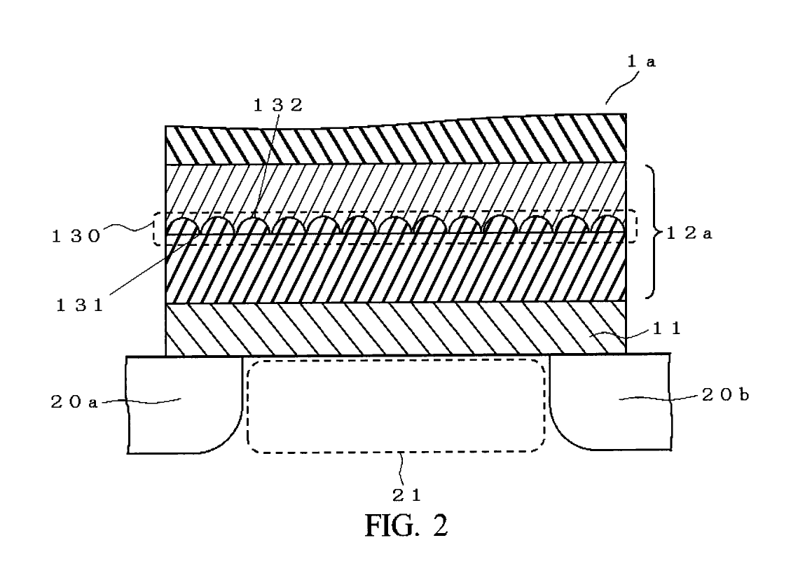

A structure of a semiconductor device 1a of a first embodiment is described with reference to FIG. 1A to FIG. 2. FIG. 1A is a cross-sectional view showing a cross-sectional structure in a direction perpendicular to a word line of a semiconductor device of a first embodiment, FIG. 1B is a cross-sectional view showing a cross-sectional structure in a direction perpendicular to a bit line of the semiconductor device of the first embodiment, and FIG. 2 is an enlarged cross-sectional view showing a structure of a charge accumulation film of the semiconductor device of the first embodiment.

The semiconductor device 1a has a semiconductor substrate 10, a tunnel insulating film 11, a charge accumulation film 12a, a block insulating film 13, and a control electrode 14 (gate electrode).

As shown in FIG. 1A, a source region 20a and a drain region 20b are formed in an upper surface of the semiconductor substrate 10. A channel formation region 21 is interposed therebetween. The tunnel insulating film 11 is formed on the source region 20a, the drain region 20b, and the channel formation region 21 of the semiconductor substrate 10. Although silicon (Si), for example, is used for the semiconductor substrate 10, the material of substrate is not limited only to silicon.

The charge accumulation film 12a is provided on the tunnel insulating film 11. As shown in FIG. 2, a rough interface 130 is formed in the charge accumulation film 12a.

The rough interface 130 has concave bottoms 131 and convex tops 132. In case of a distance from the concave bottoms 131 to the convex tops 132 is 10 nm or more, it is possible to obtain effects described below.

The block insulating film 13 is provided on the charge accumulation film 12a and the control electrode 14 (gate electrode) is provided on the block insulating film 13.

Moreover, as shown in FIG. 1B, an element-separating insulating film 30, which is made of a silicon oxide film or the like and having a STI (Shallow Trench Isolation) structure, is formed around regions of the semiconductor substrate 10. The STI is one of element isolation structure in semiconductor devices. Specifically, a shallow trench is formed in the semiconductor substrate 10 and then filled with an insulating material such as a silicon oxide film to form an element isolating region. Generally, the STI has an advantage of miniaturization of elements because of not spreading in a horizontal direction.

Although the block insulating film 13 is illustrated as a single layer in the drawings, the block insulating film 13 is not limited to the above case and may be realized by a multi-layer such as an ONO (Oxide-Nitride-Oxide) film having a laminated structure of a silicon oxide film, a silicon nitride film, and a silicon oxide film or a NONON (Nitride-Oxide-Nitride-Oxide-Nitride) film in which the ONO film is interposed between nitride films, and the like.

Next, operations of the semiconductor device 1a are described.

The semiconductor device 1a is used as an electrically erasable and programmable non-volatile semiconductor memory (Electrically Erasable and Programmable Read Only Memory; EEPROM) and the like. A writing operation is the case where electrons are injected into the charge accumulation film 12a while an erasing operation is the case where the electrons in the charge accumulation film 12a are extracted therefrom.

In the writing operation, a high voltage is applied to the control electrode 14 and electrons are thereby made to pass from the semiconductor substrate 10 through the tunnel insulating film 11 and are injected into the charge accumulation film 12a. The charge accumulation film 12a is located under the control electrode 14 while interposing the block insulating film 13 in between. In the erasing operation, a method is used in which the electrons in the charge accumulation film 12a are discharged and erased.

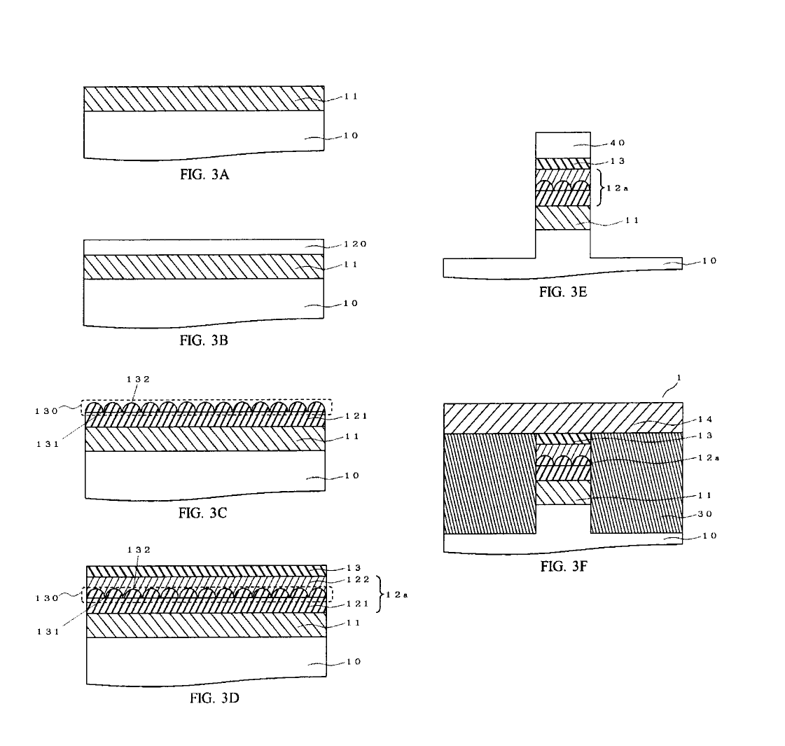

Next, a method of manufacturing the semiconductor device 1a of the first embodiment is described. FIG. 3 is a cross-sectional view showing cross sections of the semiconductor device of the first embodiment in respective manufacturing processes thereof.

As shown in FIG. 3A, the tunnel insulating film 11 is formed on the semiconductor substrate 10 by a thermal annealing in oxygen atmosphere reacting furnace (thermal oxidation). Although the thermal oxidation is given as a typical film formation method for the tunnel insulating film 11, the film may be formed by chemical vapor deposition (CVD) or the like.

Next, as shown in FIG. 3B, an amorphous silicon film 120 (precursor film) is formed on the tunnel insulating film 11 by releasing silicon hydride gas (SiH₄) or the like into a reacting furnace having predetermined reaction temperature.

The amorphous silicon film 120 is crystallized to a silicon film by annealing in an inert gas. Also, a surface of the silicon film has rough (concavo-convex shape) by surface migration. Thereafter, as shown in FIG. 3C, a silicon nitride film 121 (a first charge accumulation film) having the rough interface 130 at a surface is formed by thermal annealing in ammonia (NH₃) gas or the like nitride the silicon film. Then, an aluminum oxide film 122 (a second charge accumulation film or aluminum compound) is formed on the silicon nitride film 121 by thermal annealing in organoaluminum gas and ozone gas.

It is recommended for further increasing effect described below to be thermal anneal to be 10 nm or more distance from the concave bottoms 131 to the convex top 132 in the rough interface 130.

By performing the steps described above, the charge accumulation film 12a, which has the silicon nitride film 121 with concavo-convex shape on an interface and the aluminum oxide film 122, is formed.

The block insulating film 13 is formed on the charge accumulation film 12a and the structure shown in FIG. 3D is thus obtained. For example, if the block insulating film 13 is the ONO film, a silicon oxide film having film thickness of about 1 nm to about 10 nm is formed on the charge accumulation film 12a. A silicon nitride film having film thickness of about 1 nm to about 5 nm is formed on the silicon oxide film. And another silicon oxide film having film thickness of about 1 nm to about 10 nm is formed on the silicon nitride film. In this case, a densification processing for density growth and interlayer improvement of the block insulating film 13, and oxidation processing may be also processed.

A element-separating silicon nitride film 40 having film thickness of about 1 nm to about 10 nm is formed on the block insulating film 13 by CVD method or the like. Photoresists (not shown) are applied on the element-separating silicon nitride film 40 and the photoresists are patterned by pattern exposure. The element-separating silicon nitride film 40 is etched by using the photoresists as etching-resistant mask.

The photoresists are removed by dry-ashing method or the like, and a part of the semiconductor substrate 10, the tunnel insulating film 11, the charge accumulation film 12a and the block insulating film 13 are etched by RIE (Reactive Ion Etching) method using etched the element-separating silicon nitride film 40 as a mask. As a result, trenches for element-separating are formed and the structure shown in FIG. 3E is thus obtained.

The element-separating insulating film 30 having film thickness of about 200 nm to about 1500 nm is formed in the trenches for element-separating by coating method or the like, and the element-separating insulating film 30 is density growth by annealing under oxygen atmosphere or moisture atmosphere.

By chemical mechanical polishing (CMP) using an abrasive (slurry), which enhances a mechanical polishing effect and thereby obtains a smooth polished surface, an excess of the element-separating insulating film 30 is polished. A surface of the element-separating insulating film 30 is planarized by using the element-separating silicon nitride film 40 as stopper.

The element-separating insulating film 30 is etched to upper part of the block insulating film 13 by RIE method using the element-separating silicon nitride film 40 as a mask. The element-separating silicon nitride film 40 is removed by heat-treatment process using phosphoric acid or the like instead. The control electrode 14 is formed on the block insulating film 13 and the semiconductor device la structure shown in FIG. IF is thus obtained. The control electrode 14 is made as intended pattern by pattern exposure or the like instead (not shown).

Moreover, for example, phosphorus (P) is implanted into the semiconductor substrate 10 in a dose amount of 1×10¹⁵ cm⁻² and at incidence energy of 5 KeV by using the control electrode 14 as a mask. And the semiconductor substrate 10 is rapidly annealed at about 1000 degrees Celsius. As a result, the source region 20a and the drain region 20b are formed. Therefore, structure shown in FIG. 1A is obtained.

The manufacturing method described above is merely an example. For instance, the films may be formed not only by CVD and ALD but also by methods such as atomic layer deposition (ALD) in which growth can be controlled by the atomic layer, sputtering, physical vapor deposition (PVD), coating, and spraying.

Effects of the semiconductor device 1a of the first embodiment are described. As presented above, in case of the semiconductor device 1a provided the charge accumulation film 12a having the rough interface 130, there are many crystal defects in the rough interface 130 by difference of thermal expansion between the silicon nitride film 121 and the aluminum oxide film 122.

The defects in the rough interface 130 serve as electron-trap-sites to hold electrons in the charge accumulation film 12a when electrons are injected into the charge accumulation film 12a and held i.e. the writing operation. Therefore, pseudo electron-trap-sites is formed by forming the rough interface 130 in addition to electron-trap-sites derived from materials included the charge accumulation film 12a. It is possible to improve holding characteristic of electrons of the semiconductor device 1a i.e. a writing operation characteristic.

For example, when a charge accumulation film is thinned with miniaturizing of a semiconductor device, the charge accumulation film relatively decrease and electron-trap-sites derived from materials including in the charge accumulation film decrease. As a result electrons holding characteristic degrade.

However, in the semiconductor device 1a, the charge accumulation film 12a having the rough interface 130 is formed and pseudo electron-trap-sites is formed. Therefore, even when the charge accumulation film 12a is thinned with miniaturization of the semiconductor device 1a, it is possible to suppress effect resulting from electron-trap-sites decrease.

Although the rough interface 130 is described as a single layer in the semiconductor device 1a of the first embodiment, a number of the rough interface 130 is not limited and may be a multi-layer.

It is recommended for further increasing effect of electron-trap-sites increase to be 10 nm or more distance from the concave bottoms 131 to the convex top 132 in the rough interface 130.

Also, it is recommended for holding electrons that the rough interface 130 closes to the channel-forming region 21 which is injection side of electrons.

### Second Embodiment

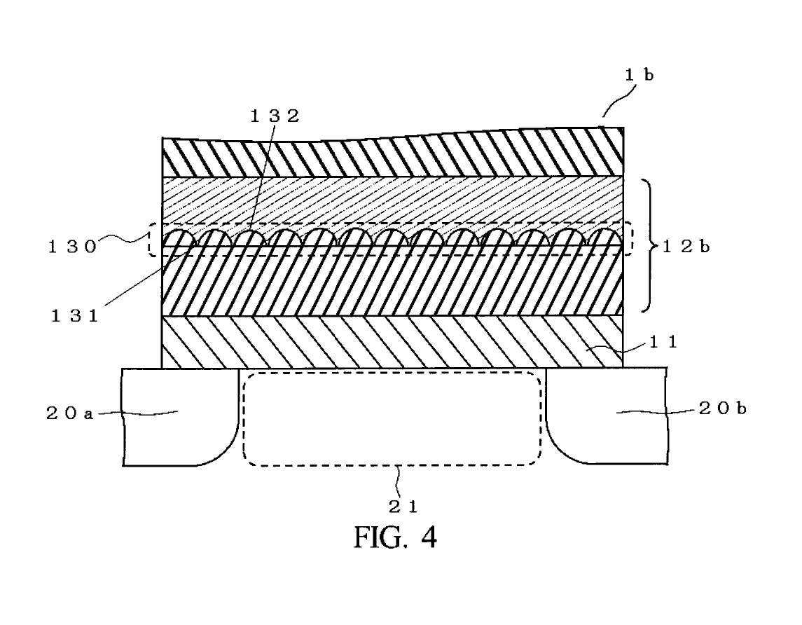

A second embodiment is described below by using FIG. 1 and FIG. 4. In the second embodiment, description of portions similar to those of the first embodiment is omitted and description is given of points which are different therefrom.

FIG. 4 is an enlarged cross-sectional view showing a structure of a charge accumulation film in of a semiconductor device of a second embodiment. The second embodiment is different from the first embodiment in that an aluminum nitride film 123 (second charge accumulation film or aluminum compound) is provided on a concavo-convex shape surface (a rough interface 130) of a silicon nitride film 121.

As shown in FIG. 1A, a semiconductor substrate 10 has a channel formation region 21 on an upper surface which is formed to be interposed between a source region 20a and a drain region 20b. And a tunnel insulating film 11 is formed on the channel formation region 21. For example, silicon (Si) is used for the semiconductor substrate 10.

A charge accumulation film 12b is provided on the tunnel insulating film 11. As shown in FIG. 4 the charge accumulation film 12b has the rough interface 130.

In case distance from a concave bottom 131 to a convex top 132 in the rough interface 130 is 10 nm or more, effects described below can further be obtained.

Then, a block insulating film 13 is formed on the charge accumulation film 12b, and a control electrode 14 (gate electrode) is formed on the block insulating film 13.

Moreover, as shown in FIG. 1B, an element-separating insulating film 30, which is made of a silicon oxide film or the like and having a STI (Shallow Trench Isolation) structure, is formed around regions of the semiconductor substrate 10 in which the memory elements are formed.

Although the block insulating film 13 is illustrated as a single layer in the drawings, the block insulating film 13 is not limited to the above case and may be realized by a multi-layer such as an ONO (Oxide-Nitride-Oxide) film having a laminated structure of a silicon oxide film, a silicon nitride film, and a silicon oxide film and the like.

Operations of the semiconductor device 1b are the same as those of the semiconductor device 1a.

Specifically, in the writing operation, a high voltage is applied to the control electrode 14 and electrons are thereby made to pass from the semiconductor substrate 10 through the tunnel insulating film 11 and are injected into the charge accumulation film 12b. The charge accumulation film 12b is located therebelow while interposing the block insulating film 13 in between. In the erasing operation, a method is used in which the electrons in the charge accumulation film 12b are discharged and erased.

A method of manufacturing the charge accumulation film 12b of the semiconductor device 1b is similar to that of the semiconductor device 1a but construction material of that differ slightly.

To be more specific, after the tunnel insulating film 11 is formed on the semiconductor substrate 10, an amorphous silicon film 120 (precursor film) is formed on the tunnel insulating film 11 with silicon hydride (SiH₄) gas introduction in a reaction tube to manufacture the semiconductor substrate 1b (as with FIG. 3B).

The amorphous silicon film 120 is crystallized to a silicon film by annealing in an inert gas. Also, a surface of the silicon film has concavo-convex shape by surface migration. Thereafter, a silicon nitride film 121 having the rough interface 130 at a surface is formed by thermal annealing in ammonia (NH₃) gas or the like nitride the silicon film. Then, an aluminum nitride film 123 is formed on the silicon nitride film 121 by thermal annealing in organoaluminum gas and ammonia gas.

It is recommended for further increasing effect described below to be thermal anneal to be 10 nm or more distance from the concave bottoms 131 to the convex top 132 in the rough interface 130.

The charge accumulation film 12b is provided by performing the steps described above. Other processes of manufacturing the semiconductor device 1b are the same as those of the semiconductor device 1a.

The manufacturing method described above is merely an example. For instance, the films may be formed not only by CVD and ALD but also by methods such as sputtering, PVD, coating, and spraying.

Here, effects of the semiconductor device 1b of the second embodiment are described.

As is the case in the semiconductor device 1a, in case of the semiconductor device 1b provided the charge accumulation film 12b having the rough interface 130, there are many crystal defects in the rough interface 130 by difference of thermal expansion between the silicon nitride film 121 and the aluminum oxide film 122.

The crystal defects in the rough interface 130 serve as electron-trap-sites to hold electrons in the charge accumulation film 12b when electrons are injected into the charge accumulation film 12b and held i.e. the writing operation. Therefore, pseudo electron-trap-sites is formed by forming the rough interface 130 in addition to electron-trap-sites derived from materials including the charge accumulation film 12b. It is possible to improve holding characteristic of electrons of the semiconductor device 1b i.e. a writing operation characteristic.

Furthermore, the aluminum nitride film 123 in the charge accumulation film 12b of the second embodiment has physical property having more electron-trap-sites than the aluminum oxide film 122. Therefore, the semiconductor device 1b has more electron-trap-sites than the semiconductor device 1a. As result writing characteristic of the semiconductor device 1b may further improve. That is, even when the charge accumulation film 12b is thinned with miniaturization of the semiconductor device 1b, it is possible to suppress effect resulting from electron-trap-sites decrease.

Although the rough interface 130 is described as a single layer in the semiconductor device 1b of the first embodiment, a number of the rough interface 130 is not limited and may be a multi-layer.

It is recommended for further increasing effect of electron-trap-sites increase to be 10 nm or more distance from the concave bottoms 131 to the convex top 132 in the rough interface 130.

Also, it is recommended for holding electrons that the rough interface 130 closes to the channel-forming region 21 which is injection side of electrons.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a semiconductor substrate;
a tunnel insulating film provided on the semiconductor substrate;
a charge accumulation film having a rough interface in the charge accumulation film provided on the tunnel insulating film;
a block insulating film provided on the charge accumulation film; and
a gate electrode provided on the block insulating film.

2. The semiconductor device according to claim 1, wherein distance from a concave bottom to a convex top in the rough interface is 10 nm or more.

3. The semiconductor device according to claim 1, wherein a plurality of rough interface provided inside the charge accumulation film.

4. The semiconductor device according to claim 1, wherein the interface forms between different elements, and one of the elements is silicon nitride.

5. The semiconductor device according to claim 1, wherein the interface forms between different elements and one of the elements is aluminum compound.

6. The semiconductor device according to claim 1, wherein thickness of the interface forms between different elements, and one of the elements provided in the tunnel insulating film side is thicker than thickness of another element provided in the gate electrode side.

7. A method of manufacturing a semiconductor device comprising:
forming a tunnel insulating film on a semiconductor substrate;
forming a precursor film on the tunnel insulating film;
forming a first charge accumulation film having rough surface formed by thermal oxidation;
forming a second charge accumulation film on the first charge accumulation film;
forming a block insulating film on the charge accumulation film; and
forming a gate electrode on the block insulating film.

8. The method according to claim 7, further comprising a step of forming multiple first charge accumulation films and second charge accumulation films.

9. The method according to claim 7, wherein the first charge accumulation film is silicon nitride.

10. The method according to claim 7, wherein the second charge accumulation film is aluminum compound.

11. The method according to claim 7, wherein thickness of the second charge accumulation film is thicker than thickness of first charge accumulation film.

12. The method according to claim 7, wherein distance from a concave bottom to a convex top in the rough surface is 10 nm or more.
